(19) United States
(12) Patent Application Publication
(10) Pub. No.: US 2009/0174032 A1
(43) Pub. Date: Jul. 9, 2009

(54) RESISTANCE CHANGE MEMORY DEVICE

(75) Inventors: Hiroshi MAEJIMA, Chigasaki-shi (JP); Katsuaki Isobe, Yokohama-shi (JP); Hideo Mukai, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/351,212

(22) Filed: Jan. 9, 2009

(30) Foreign Application Priority Data
Jan. 9, 2008 (JP) 2008-2548

(51) Int. Cl. H01L 29/00

(52) U.S. Cl. 257/536; 257/E29.001

(57) ABSTRACT

A resistance change memory device includes: a semiconductor substrate; a three dimensional cell array formed by a plurality of unit cell array blocks of two dimensional arrangement on the semiconductor substrate, the unit cell array block being formed by stacking a plurality of unit cell arrays including a first wiring, a second wiring crossing with the first wiring, and a variable resistance element connected at an intersection of the both wirings; a reading/writing/driving circuit formed on the semiconductor substrate under the three dimensional cell array; a first via region which is arranged in an end portion of the unit cell array block, and in which a via wiring for connecting the first wiring in each layer to the reading/writing/driving circuit is formed; and a second via region which is arranged in an end portion of the unit cell array block, and in which a via wiring for connecting the second wiring in each layer to the reading/writing/driving circuit is formed. When the first wiring is longer than the second wiring, the number of via arrangements in the first via region is set larger than that in the second via region.

### CROSS-REFERENCE TO RELATED APPLICATIONS

This application is based upon and claims the benefit of priority from the prior Japanese Patent Application No. 2008-2548, filed on Jan. 9, 2008, the entire contents of which are incorporated herein by reference.

### BACKGROUND OF THE INVENTION

1. Field of the Invention

The present invention relates to a resistance change memory device and more particularly, to a resistance change memory formed in three-dimensional cell array.

2. Description of the Related Art

Recently, a resistance change memory gains the spotlight as a succeeding memory of a flash memory. Here, the resistance change memory device includes a resistance change memory (ReRAM: Resistance RAM), in a narrow sense, which stores the state of resistance in a recording layer formed of transition metal oxide in a non-volatile manner and a phase change memory (PCRAM: Phase Change RAM) which uses chalcogenide or the like as a recording layer and uses the information of resistance in a crystalline state (conductor) and an amorphous state (insulator).

It is known that a variable resistance element of the ReRAM has two kinds of operation modes. One is to set a high resistance state and a low resistance state by switching polarity of applied voltage, which is called bipolar type. The other is to set a high resistance state and a low resistance state by controlling a voltage value and voltage application time without switching the polarity of the applied voltage, which is called unipolar type (for example, refer to “High Speed Unipolar Switching Resistance RAM (RRAM) Technology” written by Y. Hosoi et al, IEEE International Electron Devices Meeting 2006 Technical Digest p. 793-796).

In order to realize a high-density memory cell array, the unipolar type is preferable. In the case of the unipolar type, a cell array can be formed by stacking the variable resistance element and a rectifier element such as a diode at a cross point of a bit line and a word line without using a transistor. Further, by stacking these cell arrays three-dimensionally, high-capacity can be realized without enlarging the size of the cell array (for example, refer to Japanese Patent Application Laid-Open No. 2006-514392).

In the ReRAM of a three dimensional cell array structure, the word line and the bit line are connected to a reading/writing circuit formed on a cell array foundation substrate through a via wiring. In order to restrain the CR delay of the bit line and the word line within a certain range, it is necessary to divide the memory cell array into a plurality of memory mats on a flat plane. In this case, it becomes an issue of how to restrain an area penalty of the via wiring in order to reduce the size of cell array and chip.

### SUMMARY OF THE INVENTION

A resistance change memory device according to one aspect of the present invention includes: a semiconductor substrate; a three dimensional cell array formed by a plurality of unit cell array blocks of two dimensional arrangement on the semiconductor substrate, the unit cell array block being formed by stacking a plurality of unit cell arrays including a first wiring, a second wiring crossing with the first wiring, and a variable resistance element connected at an intersection of the both wirings; a reading/writing/driving circuit formed on the semiconductor substrate under the three dimensional cell array; a first via region which is arranged in an end portion of the unit cell array block, and in which a via wiring for connecting the first wiring in each layer to the reading/writing/driving circuit is formed; and a second via region which is arranged in an end portion of the unit cell array block, and in which a via wiring for connecting the second wiring in each layer to the reading/writing/driving circuit is formed, wherein when the first wiring is longer than the second wiring, the number of via arrangements in the first via region is set larger than that in the second via region.

A resistance change memory device according to another aspect of the present invention includes: a semiconductor substrate; a three dimensional cell array formed by a plurality of unit cell array blocks of two dimensional arrangement on the semiconductor substrate, the unit cell array block being formed by stacking a plurality of unit cell arrays including a first wiring, a second wiring crossing with the first wiring, and a variable resistance element connected at an intersection of the both wirings; a reading/writing/driving circuit formed on the semiconductor substrate under the three dimensional cell array; a first via region which is arranged in an end portion of the unit cell array block, and in which a via wiring for connecting the first wiring in each layer to the reading/writing/driving circuit is formed; and a second via region which is arranged in an end portion of the unit cell array block, and in which a via wiring for connecting the second wiring in each layer to the reading/writing/driving circuit is formed, wherein when the number of via arrangements in the first via region is smaller than that in the second via region, the first wiring is set shorter than the second wiring.

A resistance change memory device according to still another aspect of the present invention includes: a semiconductor substrate; a three dimensional cell array formed by a plurality of unit cell array blocks of two dimensional arrangement on the semiconductor substrate, the unit cell array block being formed by stacking a plurality of unit cell arrays including a first wiring, a second wiring crossing with the first wiring, and a variable resistance element connected at an intersection of the both wirings; a first via region which is arranged in an end portion of the unit cell array block, and in which a via wiring connected to the first wiring in each layer and extending in a vertical direction is formed; and a second via region which is arranged in an end portion of the unit cell array block, and in which a via wiring connected to the second wiring in each layer and extending in a vertical direction is formed, wherein when the first wiring is longer than the second wiring, the number of via arrangements in the first via region is set larger than that in the second via region.

### BRIEF DESCRIPTION OF THE DRAWINGS

FIG. 1 is a view showing the structure of a resistance change memory device having a three dimensional cell array;

FIG. 2 is a view showing an equivalent circuit of a unit cell array in the three dimensional cell array;

FIG. 3 is a view showing a stack structure of the unit cell array;

FIG. 4 is a view showing the layout of a memory mat (unit cell array block);

FIG. 5 is a cross-sectional view showing an example of via arrangement example of the word lines and the bit lines in the case of simple stack structure;

FIG. 6 is a cross-sectional view showing an example of via arrangement of the word lines and the bit lines in the case of simple stack structure;

FIG. 7 is a cross-sectional view showing an example of via arrangement of the word lines and the bit lines in the case of fully shared stack structure;

FIG. 8 is a cross-sectional view showing an example of via arrangement of the word lines and the bit lines in the case of partially shared stack structure;

FIG. 9 is a cross-sectional view showing another example of via arrangement of the word lines and the bit lines in the case of partially shared stack structure;

FIG. 10 is a view showing the via arrangement states collectively in relation to the cell array stack structure;

FIG. 11 is a view for use in describing a relation between the size of a memory mat and a via arrangement state;

FIG. 12 is a view for use in describing a relation between the size of memory mat arrangement and a via arrangement state; and

FIG. 13 is a view for use in describing a relation between the size of memory mat arrangement and a via arrangement state.

### DETAILED DESCRIPTION OF THE EMBODIMENTS

Hereinafter, referring to the drawings, an embodiment according to the invention will be described.

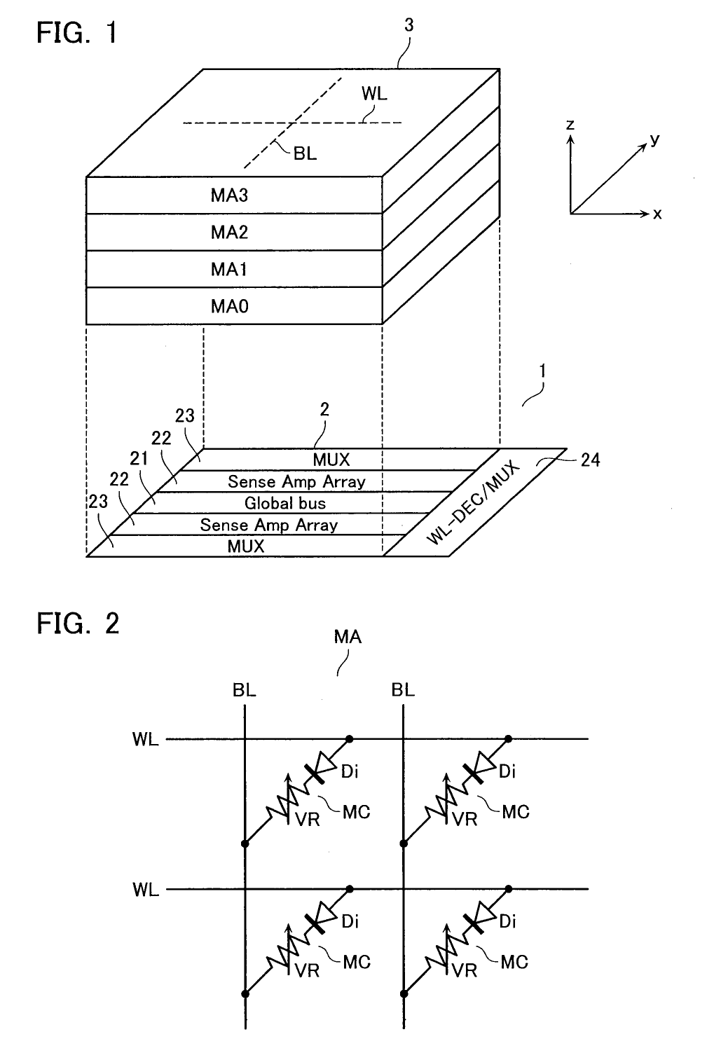

FIG. 1 shows the basic structure of a ReMAM according to the embodiment, namely, the structure of a reading/writing circuit 2 (reading/writing/driving circuit 2) on a foundation semiconductor substrate 1 and a three dimensional (3D) cell array 3 stacked thereon.

The 3D cell array 3 is formed by four layers of cell arrays MA0 to MA3 in this example. FIG. 2 shows an equivalent circuit of a unit cell array MA. As shown in the drawing, a resistance change memory device cell MC to which, for example, a diode Di and a variable resistance element VR are connected in series is arranged at an intersection of the word line WL and the bit line BL. The variable resistance element VR having, for example, a structure of electrode/transition metal oxide/electrode, brings a change in resistance of the transition metal oxide according to the conditions of the applied voltage, current, and heat, and stores the state of different resistance as information in a non-volatile manner.

The memory cell is preferably set in a stable state (reset state) with a high resistance state; for example, storing binary data makes use of a high resistance state and a low resistance state (set state). The specific example will be described later.

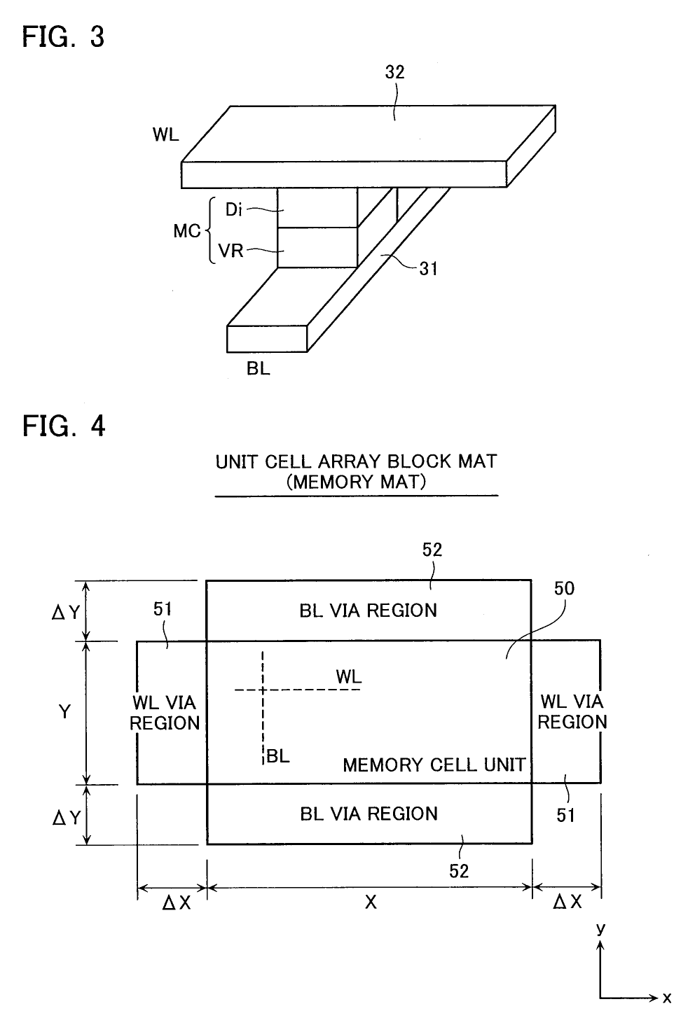

The stack structure of the unit memory cell MC is, for example, as shown in FIG. 3. The variable resistance element VR and the access element Di forming the memory cell MC are stacked together at the intersection of metal wirings 31 and 32 that are the bit line BL and the word line WL respectively.

The reading/writing circuit 2 on the substrate 1 has, for example, a global bus 21 for exchanging sense data with outside which is arranged in parallel with the word line in the midst of projection of the 3D cell array, sense amplifier arrays 22 which are arranged at the both sides of the global bus 21, and further multiplexers 23 for selecting a sense amplifier which are arranged at the outside of the sense amplifier arrays 22. One end of the global bus 21 is a decode circuit (low decoder) 24 which selects a word line of the cross point cell.

In order to connect the word line WL and the bit line BL of each cell array to the reading/writing circuit 2, wirings (via contacts) extending in a vertical direction are necessary at least at three sides of the 3D cell array. For example, a via contact is arranged along the side of one end of the word line WL and via contacts are arranged along the two sides of the both ends of the bit line BL.

FIG. 1 shows one unit cell array block with a plurality of cell arrays stacked in a z direction, and actually, a plurality of such unit cell array blocks (hereinafter, referred to as a memory mat or a mat simply) are arranged in a direction of word line WL (x direction) and a direction of bit line BL (y direction).

FIG. 4 shows the layout of one memory mat MAT including via regions. As shown in FIG. 4, the size of a memory cell unit 50 of the memory mat MAT is defined as X and Y (X: word line length, Y: bit line length) and since the size of the memory mat MAT and the whole 3D cell array in this arrangement is determined according to the width DX of word line via regions 51 arranged in the both ends of the word line and the width DY of bit line via regions 52 arranged in the both ends of the bit line, it is necessary to design it optimally. The width DX and the width DY are determined by the number of via arrangements and by how to share the vias between the cell arrays. Hereinafter, it will be described in detail.

Before thinking about a two dimensional arrangement of a memory mat, a relation between a sharing state of the bit line BL and the word line WL between the cell arrays in the 3D cell array and the number of the bit line vias and the word line vias will be described, which has not been described in FIG. 1.

At first, a mode of sharing a bit line and a word line includes the following three types: (1) the case of “simple stack structure” in which neither bit line nor word line is shared among the cell arrays, (2) the case of “fully shared stack structure” in which the bit lines and the word lines are fully shared among the cell arrays, and (3) the case of “partially shared stack structure” in which either the bit lines or the word lines are shared among the cell arrays.

Then, the structure of sharing a via is determined according to the relation of the above structure of sharing the bit lines and the word lines. Hereinafter, the arrangement structure of the bit line vias and the word line vias will be described specifically. In the following description, the number of word line vias arranged in a direction of word line and the number of bit line vias arranged in a direction of bit line are called the number of via arrangements (or simply called the number of vias).

In the following description, the number of cell array layers is defined as 2N, the number of cell arrays which share one word line via is defined as m, and the number of cell arrays which share one bit line via is defined as n. Each maximum value of n and m is N and magnitude relation thereof is determined depending on the structure of sharing the word lines and the bit lines.

[Simple Stack Structure]

When one of the word line and the bit line is shared among the adjacent cell arrays, basically, the other must be independent in each of the adjacent cell arrays. For example, when the word lines in respective layers are connected in common through one via, it is necessary to prepare each independent via for the bit line in each layer.

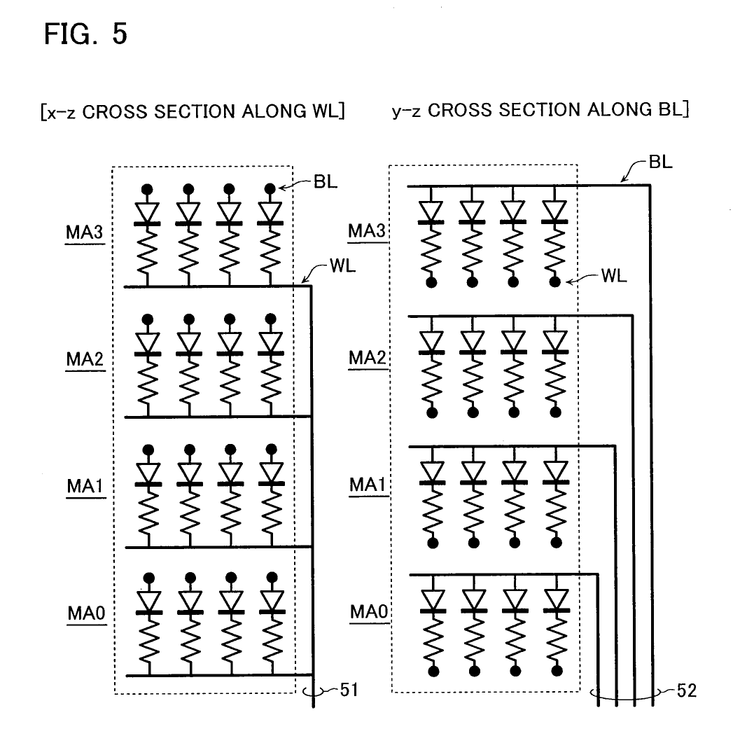

FIG. 5 shows the x-z cross section along the word line WL and the y-z cross section along the bit line BL in the memory mat and an example of the via structure of the word lines and the bit lines in the case of the simple stack structure. Here, it shows the state in which the word line via region 51 is connected to the foundation substrate only by a line of vias, in other words, the word lines WL in all the layers are connected together to the foundation substrate through a common via, and four lines of vias separately formed by each bit line in each layer are derived from the bit line via region 52 and separately connected to the foundation substrate.

In the case of the simple stack structure, generally, the word line via region 51 has 2N/m of via arrangements, the bit line via region 52 has 2N/n of via arrangements, and mn=2N. The example of FIG. 5 shows the case in which m=1 and n=4 in the range of four layered cell array (2N=4).

In the case of the simple stack structure of 2N=4, the following via arrangement structures of the word line and the bit line are possible: (1) m=1 and n=4, (2) m=2 and n=2, and (3) m=4 and n=1.

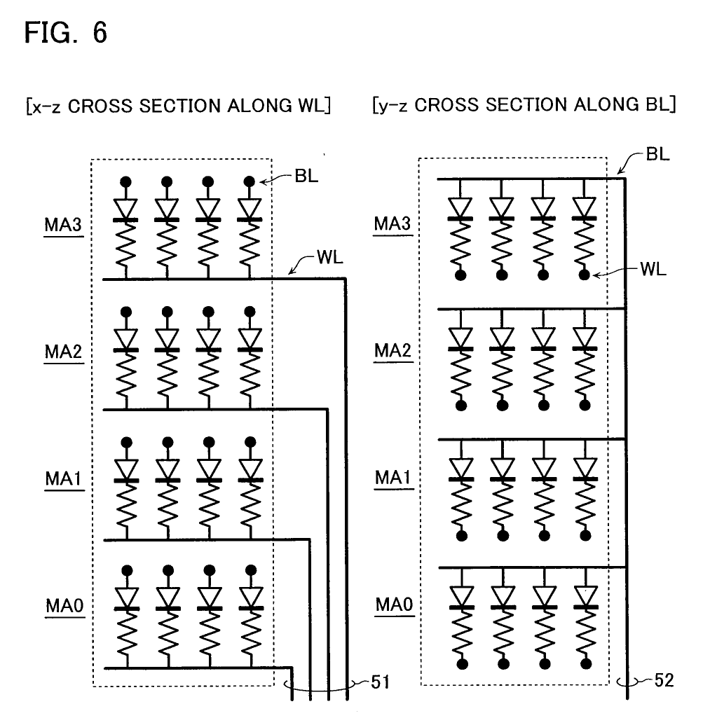

FIG. 6 shows an example of the via arrangement in the above (3). In other words, the respective word lines in the respective layers are derived from the respective word line via regions 51 (the number of the via arrangements m=4), while the bit line via regions 52 in the respective layers are connected through the common bit line (the number of the via arrangements n=1).

[Fully Shared Stack Structure]

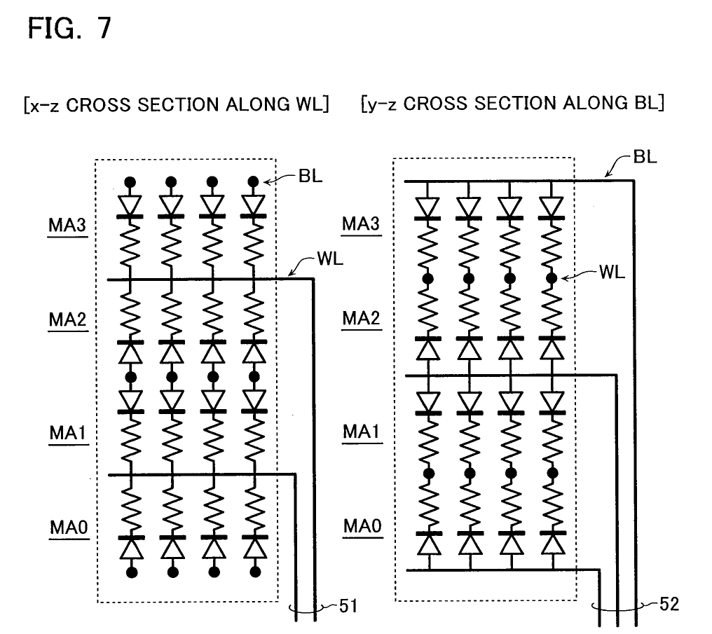

FIG. 7 shows the x-z cross section along the word line WL, the y-z cross section along the bit line BL, and an example of the via arrangement structure of the word line and the bit line, in the memory mat of the fully shared stack structure. In the case of fully sharing the word lines and the bit lines between the adjacent cell arrays, the word lines and the bit lines in the respective layers are connected to the foundation substrate respectively through the respective independent vias.

In the example of FIG. 7, in the case of 2N=4, the number of the via arrangements in the word line via region 51 is N/m=2 and the number of the via arrangements in the bit line via region 52 is (N+1)/n=3. The number of the via arrangements of the word line is (N+1)/m and the number of the via arrangements of the bit line is N/n when exchanging the word line and the bit line with each other in the relation between the word line and the bit line.

[Partially Shared Stack Structure]

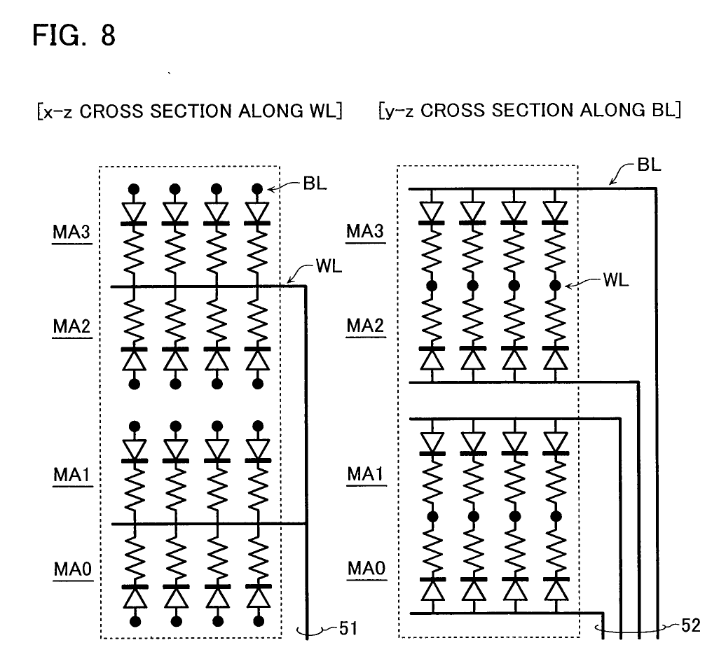

FIG. 8 shows the x-z cross section along the word line WL, the y-z cross section along the bit line BL, and an example of the via wiring structure of the word line and the bit line in the memory mat of the partially shared stack structure. In the case of sharing either the word line or the bit line between the adjacent cell arrays, one of the number of the word lines and the number of the bit lines is 2N and the other is N.

FIG. 8 shows the case in which 2N=4 and the word line in each layer is shared between the cell arrays and each bit line is independent, in other words, the word lines in all the layers are connected together to the word line via region 51 as one via, and the bit line via region 52 has four via arrangements in order to take out the bit lines in the respective layers independently.

Generally, when the word line via is shared in m-layer and the bit line via is shared in n-layer, the number of the via arrangements of the word line is 2N/m (or N/m), and the number of the via arrangements of the bit line is 2N/n (or N/n).

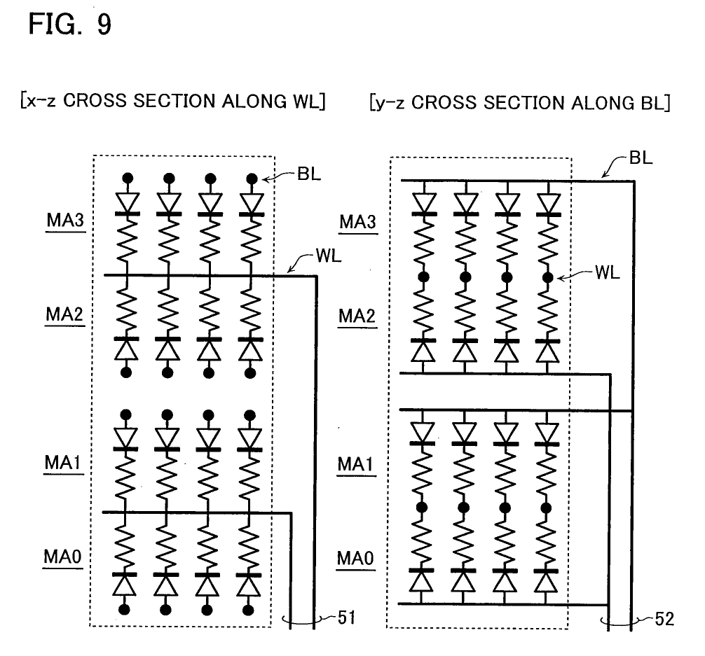

FIG. 8 shows the example of m=4 and n=1. The example of m=2 and n=2 is shown in FIG. 9 for comparison with the example of FIG. 8. In this case, the word line via region 51 and the bit line via region 52 have two via arrangements respectively.

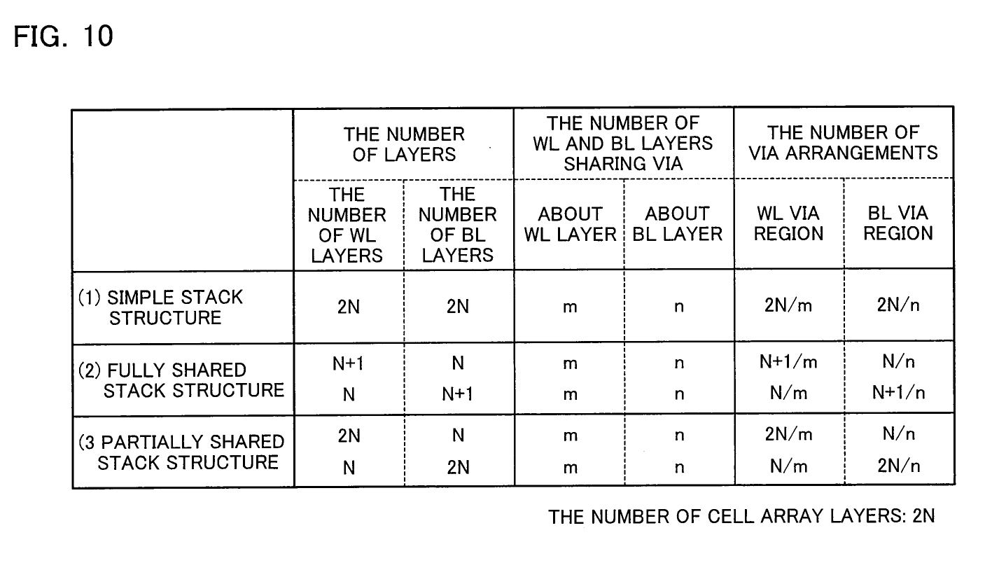

FIG. 10 collectively shows a via sharing state of the word line via region and the bit line via region and the number of via arrangements with respect to the cell array stack structure as mentioned above.

[Memory Mat Size and Via Arrangement Method]

Next, a via arrangement method for reducing the memory mat size will be described.

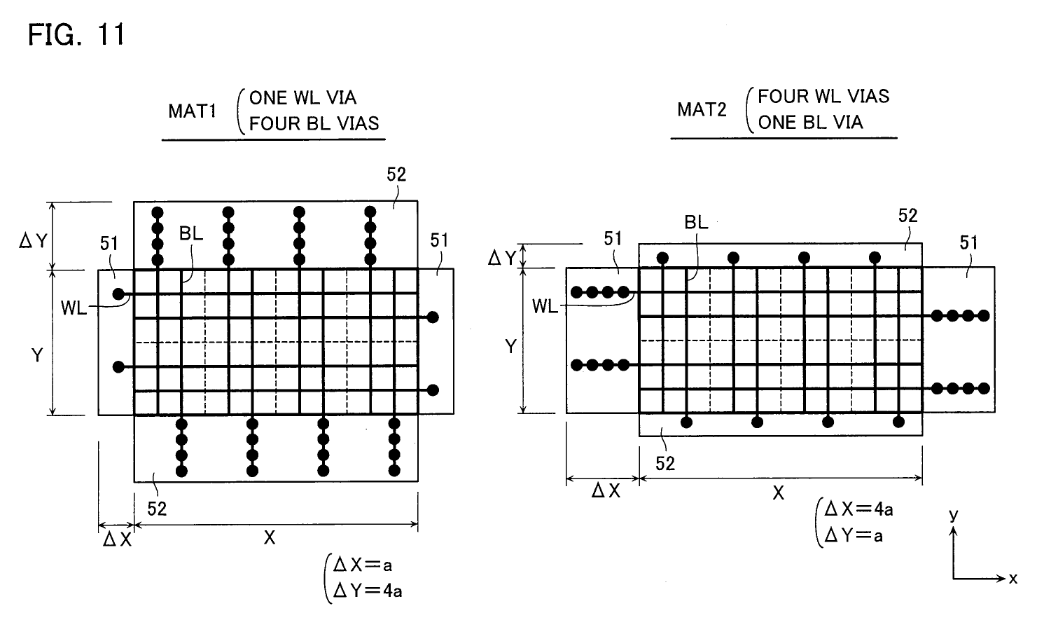

Based on the layout of the memory mat MAT in FIG. 4, FIG. 11 shows a comparison between a memory mat MAT 1 which has the word line via region 51 including one via arrangement and the bit line via region 52 including four via arrangements and a memory mat MAT 2 which has the word line via region 51 including four via arrangements and the bit line via region 52 including one via arrangement. The size of the memory cell unit 50 (the word line length X and the bit line length Y) is identical in the both.

In this case, when the widths DX and □Y of the via region have the equal via arrangement pitch “a”, in the MAT 1, DX=a and DY=4a and in the MAT 2, DX=4a and DY=a.

When the memory mat size defined by the outer frame of the bit line and word line via regions is required, in the MAT 1, S1=(X+2DX) (Y+2DY)=(X+2a) (Y+8a) and in the MAT 2, S2=(X+2DX) (Y+2DY)=(X+8a) (Y+2a). A difference in the size becomes S1-S2=6a (X−Y). Therefore, when the size of the memory cell unit 50 is X>Y, the memory mat size becomes S1>S2 and the MAT 2 is smaller than the MAT 1 in size.

The above is generalized as follows. The word line and the bit line are defined as the first wiring and the second wiring generally and the via regions corresponding to these are defined as the first via region and the second via region respectively. When the via arrangement pitch is equal in the via regions and the first wiring is longer than the second wiring, the number of the via arrangements of the first via region is increased more than that of the second via region. Therefore, it is possible to make the memory mat size including the via region smaller than in the contrary case.

A preferred condition to reduce the memory mat size will be described as follows, with respect to the sharing structure of the word line and the bit line in the respective layers described in FIGS. 5 to 9.

In the example of the simple stack structure in FIG. 5, the bit line length Y is preferably larger than the word line length X in order to reduce the memory mat size. On the contrary, in the example of the simple stack structure in FIG. 6, the word line length X is preferably larger than the bit line length Y in order to reduce the memory mat size.

In the example of the fully shared stack structure in FIG. 7, the bit line length Y is preferably larger than the word line length X in order to reduce the memory mat size. Though it is not illustrated in the drawings, when the cell polarity in the respective layers is reversed, the relation between the bit line and the word line is reversed and the word line length is preferably larger than the bit line length in order to reduce the memory mat size.

In the example of the partially stack structure in FIG. 8, the bit line length Y is preferably larger than the word line length X in order to reduce the memory mat size. Though it is not illustrated in the drawings, when the cell polarity in each layer is reversed, the bit line in each layer is shared, and each word line is independent, it is preferable on the contrary that the word line length be larger than the bit line length in order to reduce the memory mat size.

[Size of Memory Mat Arrangement and Via Arrangement Method]

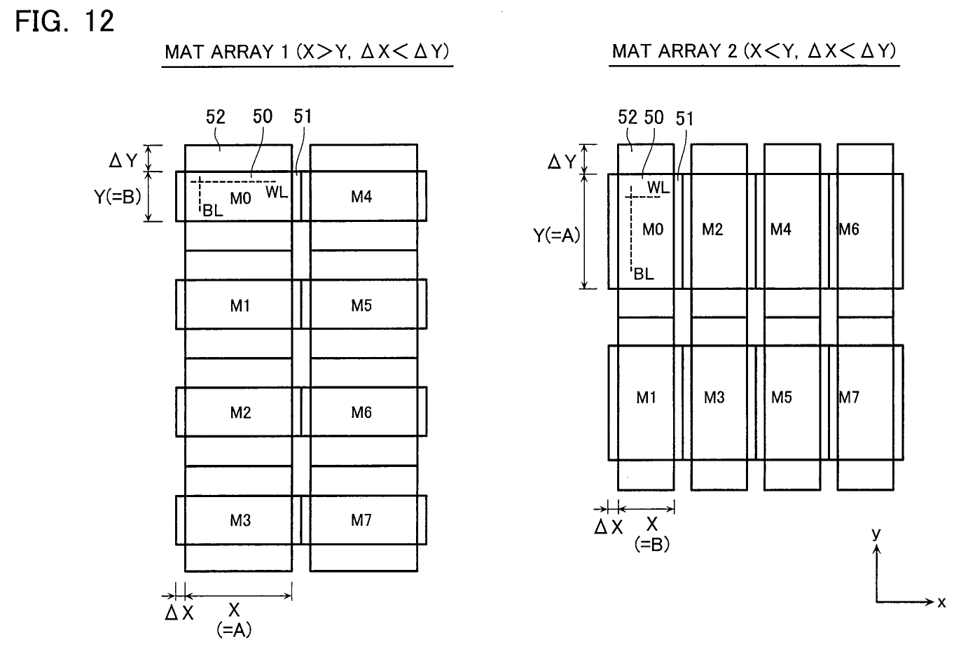

Next, a preferred condition to reduce the size when a plurality of memory mats are arranged will be described referring to FIG. 12. FIG. 12 shows two memory mat arrangements: MAT-ARRAY 1 and MAT-ARRAY 2.

In the memory cell unit 50 of each memory mat, the word line length is X=A and the bit line length is Y=B in the MAT-ARRAY 1, the word line length is X=B and the bit line length is Y=A in the MAT-ARRAY 2, and the size is the same A□B in the both. On the other hand, the width DX of the word line via region 51 and the width DY of the bit line via region 52 satisfy the relation DX<DY in the both.

For example, A is about twice as long as B, and two memory mats are arranged in the x direction and four mats are arranged in the y direction in the MAT-ARRAY 1; while four mats are arranged in the x direction and two mats are arranged in the y direction in the MAT-ARRAY 2, so that eight memory mats M0 to M7 may be as square as possible.

The magnitude relation between the two memory mat arrangements MAT-ARRAY 1 and MAT-ARRAY 2 is determined depending on the magnitude relation of the size between the word line via region 51 and the bit line via region 52 since the memory cell unit 50 has the same size. In this example in which the width DY of the word line via region 51 (namely, the number of via arrangements) is larger than the width DX of the bit line via region 52 (namely, the number of via arrangements), the size of the mat arrangement MAT-ARRAY 1 which has the larger bit line via region 52 X□DY is larger than that of the MAT-ARRAY 2 apparently. From the viewpoint of size reduction, the arrangement method of the MAT-ARRAY 2 is preferable to that of the MAT-ARRAY 1.

When it has the same word line length X and the same bit line length Y as the memory mat MAT-ARRAY 1, it is preferable that the number of via arrangements in the bit line via region 52 be smaller than that in the word line via region 51, in order to realize a smaller size than in the memory mat MAT-ARRAY 1, as shown in FIG. 11. This holds true for the case of considering the size of the mat arrangement.

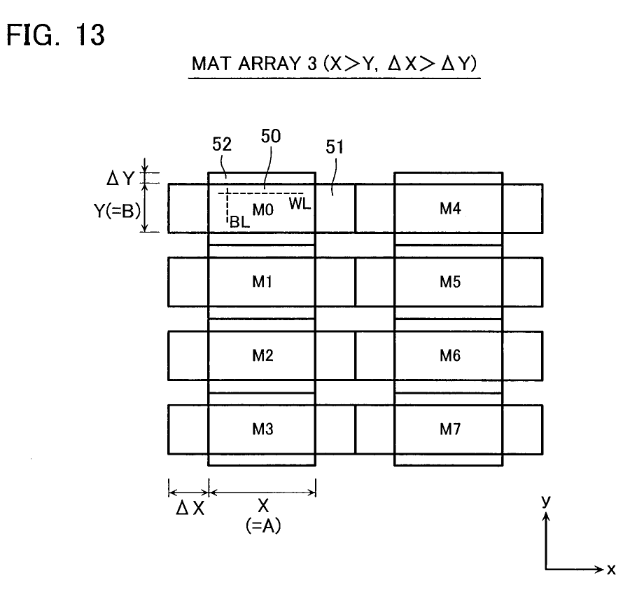

FIG. 13 shows a memory mat MAT-ARRAY 3 having the same word line length X and the same bit line length Y as those of the memory mat MAT-ARRAY 1 in FIG. 12 and having the smaller number of the via arrangements of the bit line via region 52 than that of the word line via region 51 (DX>DY) similarly to the two dimensional arrangement of the MAT-ARRAY 1. Apparently, its size is the same as that of the MAT-ARRAY 2 and smaller than that of the MAT-ARRAY 1.

About the above-mentioned memory mat arrangement, the word line and the bit line are generally defined as the first and second wirings respectively and the word line via region and the bit line via region are defined as the first via region and the second via region respectively. In order to reduce the mat arrangement on the whole, it is preferable that, when the number of the via arrangements of the first via region is smaller than that of the second via region, the first wiring be set shorter than the second wiring (the MAT-ARRAY 2 of FIG. 12) and that when the number of the via arrangements of the first via region is larger than that of the second via region, the first wiring be set longer than the second wiring (the MAT-ARRAY 3 of FIG. 13).

What is claimed is:

1. A resistance change memory device comprising:
a semiconductor substrate;
a three dimensional cell array formed by a plurality of unit cell array blocks of two dimensional arrangement on the semiconductor substrate, the unit cell array block being formed by stacking a plurality of unit cell arrays including a first wiring, a second wiring crossing with the first wiring, and a variable resistance element connected at an intersection of the both wirings;
a reading/writing/driving circuit formed on the semiconductor substrate under the three dimensional cell array;
a first via region which is arranged in an end portion of the unit cell array block, and in which a via wiring for connecting the first wiring in each layer to the reading/writing/driving circuit is formed; and
a second via region which is arranged in an end portion of the unit cell array block, and in which a via wiring for connecting the second wiring in each layer to the reading/writing/driving circuit is formed,
wherein when the first wiring is longer than the second wiring, the number of via arrangements in the first via region is set larger than that in the second via region.

2. The resistance change memory device according to claim 1, wherein the first wiring and the second wiring are stacked mutually independently among the respective layers in the unit cell array.

3. The resistance change memory device according to claim 1, wherein the first wiring and the second wiring are stacked such that at least one of them is shared among the respective layers in the unit cell array.

4. The resistance change memory device according to claim 1, wherein the first wiring and the second wiring are stacked such that the both are shared among the respective layers in the unit cell array.

5. The resistance change memory device according to claim 1, wherein the unit cell array has an access element connected to the variable resistance element in series.

6. The resistance change memory device according to claim 5, wherein the access element is a diode.

7. The resistance change memory device according to claim 1, wherein the variable resistance element has a structure of electrode/transition metal oxide/electrode, and
the transition metal oxide is formed to produce a change of resistance value according to an applied condition of any of voltage, electric current, and heat.

8. A resistance change memory device comprising:
a semiconductor substrate;
a three dimensional cell array formed by a plurality of unit cell array blocks of two dimensional arrangement on the semiconductor substrate, the unit cell array block being formed by stacking a plurality of unit cell arrays including a first wiring, a second wiring crossing with the first wiring, and a variable resistance element connected at an intersection of the both wirings;
a reading/writing/driving circuit formed on the semiconductor substrate under the three dimensional cell array;
a first via region which is arranged in an end portion of the unit cell array block, and in which a via wiring for connecting the first wiring in each layer to the reading/writing/driving circuit is formed; and
a second via region which is arranged in an end portion of the unit cell array block, and in which a via wiring for connecting the second wiring in each layer to the reading/writing/driving circuit is formed,
wherein when the number of via arrangements in the first via region is smaller than that in the second via region, the first wiring is set shorter than the second wiring.

9. The resistance change memory device according to claim 8, wherein the first wiring and the second wiring are stacked mutually independently among the respective layers in the unit cell array.

10. The resistance change memory device according to claim 8, wherein the first wiring and the second wiring are stacked such that at least one of them is shared among the respective layers in the unit cell array.

11. The resistance change memory device according to claim 8, wherein the first wiring and the second wiring are stacked such that the both are shared among the respective layers in the unit cell array.

12. The resistance change memory device according to claim 8, wherein the unit cell array has an access element connected to the variable resistance element in series.

13. The resistance change memory device according to claim 12, wherein the access element is a diode.

14. The resistance change memory device according to claim 8, wherein the variable resistance element has a structure of electrode/transition metal oxide/electrode, and
the transition metal oxide is formed to produce a change of resistance value according to an applied condition of any of voltage, electric current, and heat.

15. A resistance change memory device comprising:
a semiconductor substrate;
a three dimensional cell array formed by a plurality of unit cell array blocks of two dimensional arrangement on the semiconductor substrate, the unit cell array block being formed by stacking a plurality of unit cell arrays including a first wiring, a second wiring crossing with the first wiring, and a variable resistance element connected at an intersection of the both wirings;
a first via region which is arranged in an end portion of the unit cell array block, and in which a via wiring connected to the first wiring in each layer and extending in a vertical direction is formed; and
a second via region which is arranged in an end portion of the unit cell array block, and in which a via wiring connected to the second wiring in each layer and extending in a vertical direction is formed,
wherein when the first wiring is longer than the second wiring, the number of via arrangements in the first via region is set larger than that in the second via region.

16. The resistance change memory device according to claim 15, wherein the first wiring and the second wiring are stacked mutually independently among the respective layers in the unit cell array.

17. The resistance change memory device according to claim 15, wherein the first wiring and the second wiring are stacked such that at least one of them is shared among the respective layers in the unit cell array.

18. The resistance change memory device according to claim 15, wherein the first wiring and the second wiring are stacked such that the both are shared among the respective layers in the unit cell array.

19. The resistance change memory device according to claim 15, wherein the unit cell array has an access element connected to the variable resistance element in series.

20. The resistance change memory device according to claim 19, wherein the access element is a diode.
